(19) United States
(12) Patent Application Publication
(10) Pub. No.: US 2023/0215678 A1
(43) Pub. Date: Jul. 6, 2023

(54) ELECTRONICALLY-TUNABLE, AIR-STABLE, NEGATIVE ELECTRON AFFINITY SEMICONDUCTOR PHOTOCATHODE

(71) Applicant: University of Southern California, Los Angeles, CA (US)

(72) Inventors: Rehan KAPADIA, Glendale, CA (US); Hyun Uk CHAE, Los Angeles, CA (US); Ragib AHSAN, Los Angeles, CA (US); Subrata DAS, Los Angeles, CA (US)

(21) Appl. No.: 17/940,113

(22) Filed: Sep. 8, 2022

Related U.S. Application Data
(60) Provisional application No. 63/241,708, filed on Sep. 8, 2021.

(51) Int. Cl. H01J 1/34

(52) U.S. Cl. CPC H01J 1/34; H01L 31/0224

(57) ABSTRACT

A HELAC device includes a semiconductor layer that absorbs incident photons, a graphene monolayer disposed over the semiconductor layer, and an insulator layer interposed between the semiconductor layer and graphene monolayer. The graphene monolayer is configured as a gate for the HELAC device while the insulator layer is configured to allow a voltage drop between the semiconductor layer and graphene. Advantageously, the HELAC device is configured to receive photons on an emitter surface and to emit hot electrons therefrom.

### CROSS-REFERENCE TO RELATED APPLICATIONS

This application claims the benefit of U.S. Provisional Application Serial No. 63/241,708 filed Sep. 8, 2021, the disclosure of which is hereby incorporated in its entirety by reference herein.

### STATEMENT REGARDING FEDERALLY SPONSORED RESEARCH OR DEVELOPMENT

The invention was made with Government support under Contract No. DE-SC0021213 awarded by the U.S. Department of Energy. The Government has certain rights to the invention.

### TECHNICAL FIELD

In at least one aspect, the present invention relates to negative electron affinity semiconductor photocathode.

### BACKGROUND

The modern-day congested and contested electromagnetic spectrum has placed stringent demands on electronic systems[1, 2]. A single electromagnetic (EM) source that changes transmission bands, multiple frequencies, or even frequency bands and is able to quickly switch frequencies when the desired communication channels become contested is of value in a contested environment.

Electron emission cathodes are used in a wide variety of applications, including but not limited to, electron microscopes[15, 16], electron beam lithography[17], space propulsion[18], high power microwave (HPM) devices[19-21],, free-electron lasers[22], and displays[23]. HPM sources for millimeter-wave and terahertz radiation are of great interest for military and defense applications such as radar, electronic countermeasures, and communications[20, 24]. While photo-assisted field emission devices have been explored in the past[25],[26],[27],[28],[29], as promising high-frequency emitter, these are generally studied utilizing free-space optics to directly focus a laser on a tip or tip array, and use p-type silicon to enable photogating of field emission. Recently, simulation and experimental results have shown that optically driven emitters[30-37] could play a valuable role in cathodes for high-power microwave and vacuum electron devices in general.

Generating ultra-fast electron pulse trains from a low-power optical signal with stable electron emitters has been a key goal for vacuum electron emitters[33, 34, 36, 38-42]. Photo-gated semiconductor field emitters have been explored in the past due to the possibility of stable, ultrafast modulation with a low-power laser. The introduction of the laser enables significant reduction of the gate-emitter capacitance, which is a key limiter for field emitter array response times. Thus far, the majority of devices explored have been p-type semiconductors [39, 43-45], primarily silicon, made into sharp tips with local metal gates encircling the tips. Such emitters do not have a large supply of electrons due to the p-type semiconductor doping, so the voltage is used to bring the emitter to the edge of emission, and the optical pulse is used to modulate the supply function. Experimental results for such samples have been promising, with the best emitter arrays demonstrating a pulse full width half maximum (FWHM) of ~80 ps [39]. However, the efficiency of such emitter arrays has been limited, with quantum efficiencies of < 0.05%. Thus, to get 1 mA of current from the emitter would require a >2 W laser, limiting the compactness of the system. Thus far, these systems have primarily been fabricated out of semiconductors that absorb primarily visible and near-infrared light, such as Si.

The combination of visible light-based emitters and high powers necessary also prevent the use of state-of-the-art (SOA) commercial laser amplitude modulators, which are primarily developed for optical telecom wavelengths, between 1300 nm-1600 nm. However, even with SOA commercial modulators, it is a challenge to effectively modulate beams at the watt level. However, ~200 mW level beams can be modulated at >20 GHz frequencies. This implies that devices sensitive to telecom wavelength photons exhibiting photon-to-electron quantum efficiencies of 10-30% are required in order to get modulated currents in the 10-100 mA range.

Accordingly, there is a need for improved negative electron affinity semiconductor photocathode.

### SUMMARY

In at least one aspect, a Hot Electron Laser-Assisted Cathode (HELAC) device is provided. The HELAC device includes a semiconductor layer that absorbs incident photons, a graphene monolayer disposed over the semiconductor layer, and an insulator layer interposed between the semiconductor layer and graphene monolayer. The graphene monolayer is configured as a gate for the HELAC device while the insulator layer is configured to allow a voltage drop between the semiconductor layer and graphene. Advantageously, the HELAC device is configured to receive photons on an emitter surface and to emit hot electrons therefrom.

In another aspect, a photo-gated emitter termed Hot Electron Laser-Assisted Cathode (HELAC) that is sensitive to 1550 nm photons, with quantum efficiencies of >30%, and pulse FWHMs down to 5 ps is provided. This is achieved by utilizing III-V semiconductors typically used in telecom devices, a planar geometry, and a gate that is simultaneously electron and optically transparent.

In another aspect, the HELAC device set forth herein has the following properties: high-quantum efficiency with current densities up to 1 A/cm²; highly scalable planar geometry, eliminating sensitive field enhancement structures; sensitivity to telecommunication wavelengths to leverage commercial laser infrastructure; and modulation rates of up to 250 GHz

In another aspect, the HELAC device is comprised of a semiconductor or semimetal absorber, an insulator, and a metal emitter.

In another aspect, the HELAC device is comprised of a semiconductor or semimetal absorber, an insulator, and a semiconductor emitter.

In another method, a method for fabricating a Hot Electron Laser-Assisted Cathode (HELAC) device is provided. The method includes a step of epitaxially depositing a semiconductor layer over a top face of a wafer substrate. An insulator layer is deposited over the semiconductor layer by atomic layer deposition and/or plasma-enhanced chemical vapor deposition. A bottom contact is deposed over the bottom face of the wafer substrate. A graphene layer is transferred onto the insulator layer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be made to the following detailed description, read in conjunction with the following drawings, wherein like reference numerals denote like elements and wherein:

FIGS. 1A, 1B, and 1C. A) Schematic of HELAC device. B) Zoomed in band diagram at semiconductor-insulator-graphene junction with zero applied bias between semiconductor and graphene. Blue circle with arrow shows the electron tunneling process from the semiconductor into the graphene. C) Zoomed in band diagram but with three volts applied bias between the semiconductor and graphene.

FIG. 2. Schematic of a III-V HELAC sensitive to telecom wavelengths.

FIG. 3. HELAC fabrication step-by-step schematic.

FIGS. 4A and 4B. A) Proof-of-Concept experimental demonstration device structure and measurement setup. B) Emission current for a fixed anode voltage of 40 V and a varying voltage between the silicon and graphene. Despite an anode voltage of 40 V with a spacing of 5 mm, emission current due to hot electrons is observed to be injected into the graphene from the silicon substrate.

FIGS. 5A and 5B. A) Energy above the Dirac point electrons will be injected for InGaAs HELAC. B) Expected photoemission EQE as a function of diode voltage.

FIGS. 6A, 6B, and 6C. A) Graphene density of states used for computing carrier scattering. B) Calculated scattering rates in graphene. C) Predicted energy vs time trajectories for electrons injected into graphene at different energies E_{Hot} above the Dirac point.

### DETAILED DESCRIPTION

Reference will now be made in detail to presently preferred embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4.... 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits.

When referring to a numerical quantity, in a refinement, the term “less than” includes a lower non-included limit that is 5 percent of the number indicated after “less than.” A lower non-includes limit means that the numerical quantity being described is greater than the value indicated as a lower non-included limited. For example, “less than 20” includes a lower non-included limit of 1 in a refinement. Therefore, this refinement of “less than 20” includes a range between 1 and 20. In another refinement, the term “less than” includes a lower non-included limit that is, in increasing order of preference, 20 percent, 10 percent, 5 percent, 1 percent, or 0 percent of the number indicated after “less than.”

For any device described herein, linear dimensions and angles can be constructed with plus or minus 50 percent of the values indicated rounded to or truncated to two significant figures of the value provided in the examples. In a refinement, linear dimensions and angles can be constructed with plus or minus 30 percent of the values indicated rounded to or truncated to two significant figures of the value provided in the examples. In another refinement, linear dimensions and angles can be constructed with plus or minus 10 percent of the values indicated rounded to or truncated to two significant figures of the value provided in the examples.

With respect to electrical devices, the term “connected to” means that the electrical components referred to as connected to are in electrical communication. In a refinement, “connected to” means that the electrical components referred to as connected to are directly wired to each other. In another refinement, “connected to” means that the electrical components communicate wirelessly or by a combination of wired and wirelessly connected components. In another refinement, “connected to” means that one or more additional electrical components are interposed between the electrical components referred to as connected to with an electrical signal from an originating component being processed (e.g., filtered, amplified, modulated, rectified, attenuated, summed, subtracted, etc.) before being received to the component connected thereto.

The term “electrical communication” means that an electrical signal is either directly or indirectly sent from an originating electronic device to a receiving electrical device. Indirect electrical communication can involve processing of the electrical signal, including but not limited to, filtering of the signal, amplification of the signal, rectification of the signal, modulation of the signal, attenuation of the signal, adding of the signal with another signal, subtracting the signal from another signal, subtracting another signal from the signal, and the like. Electrical communication can be accomplished with wired components, wirelessly connected components, or a combination thereof.

The term “one or more” means “at least one” and the term “at least one” means “one or more.” The terms “one or more” and “at least one” include “plurality” as a subset.

The term “substantially,” “generally,” or “about” may be used herein to describe disclosed or claimed embodiments. The term “substantially” may modify a value or relative characteristic disclosed or claimed in the present disclosure. In such instances, “substantially” may signify that the value or relative characteristic it modifies is within ± 0%, 0.1%, 0.5%, 1%, 2%, 3%, 4%, 5% or 10% of the value or relative characteristic.

In drawings of multilayer structures, layers drawn as contacting each other can contact each other. In a refinement, one or more additional layers can be interposed between the layers drawn as contacting each other. The term “disposed over” encompasses the situation when two layers contact each other and when additional layers are interposed between two layers drawn as contacting each other.

Throughout this application, where publications are referenced, the disclosures of these publications in their entireties are hereby incorporated by reference into this application to more fully describe the state of the art to which this invention pertains.

### Abbreviations

“EQE” means external quantum efficiency.

“HELAC” means Hot Electron Laser-Assisted Cathode.

“NA” is the number density of acceptor atoms added to a semiconductor.

“ND” is the number density of donor atoms added to a semiconductor.

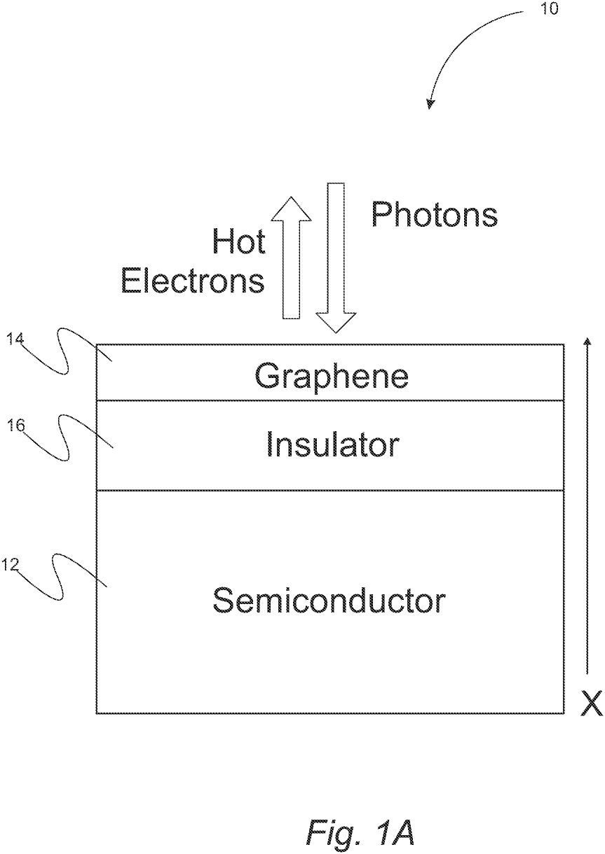

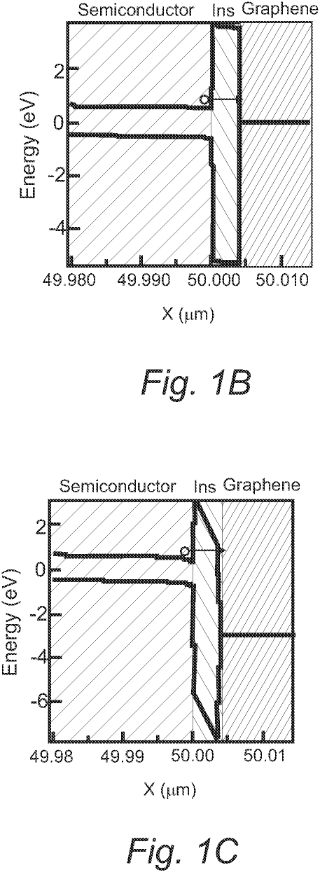

With reference to FIGS. 1A, 1B, and 1C, the basic operating principle of the HELAC is schematically illustrated. HELAC device 10 includes semiconductor layer 12, which absorbs incident photons deposited onto a wafer substrate as set forth below. A monolayer 14 of graphene, which acts as the gate, is disposed over semiconductor 12. In a refinement, a small number of graphene can be used (e.g., 1 to 5 layers of graphene). The thickness of a monolayer of graphene is about 0.345 nm plus/minus 10 percent. Insulator layer 16 is interposed between the semiconductor layer 12 and graphene layer 14. Though not particularly limited by the thickness of the insulator layer 16, the thickness of the insulator layer is typically from about 5 nm to 50 nm, with a thickness of about 10 nm being optimal. Insulator layer 16 allows a voltage drop between the semiconductor and graphene. Therefore, HELAC device 10 can be in electrical communication with a power supply for positively biasing the graphene monolayer relative to the semiconductor layer. As depicted in FIG. 1A, HELAC 10 is configured to receive photons on the graphene side and emit hot electrons from that same side.

Electron emission properties for the device depicted in FIGS. 1B and 1C are provided in FIGS. 1B and 1C. The general device concept of FIG. 1A can be used to demonstrate hot-electron electrochemistry can be carried out [48-50]. FIG. 1B shows a band diagram simulated with TCAD Sentaurus, at the semiconductor-insulator-graphene junction. When a small bias is applied across the junction, electrons from the silicon conduction band will tunnel into the graphene with energies close to the Fermi level. These low-energy electrons will simply scatter with electrons and phonons in graphene and then be collected as current from the graphene contact. However, when 3 V is applied across the device, FIG. 1C shows that the electrons injected into the graphene will have energy significantly greater than the Fermi level. As more bias is applied to the junction, the injected electrons will have energy greater than the graphene work function and will be emitted into the vacuum. This is similar to the effect of a negative electron affinity coating, such as cessiation of a surface, but is completely air stable and electrically tunable. To operate these devices, a bias will first be applied across the semiconductor-graphene junction, and then a pulsed laser will modulate the emitted electron beam.

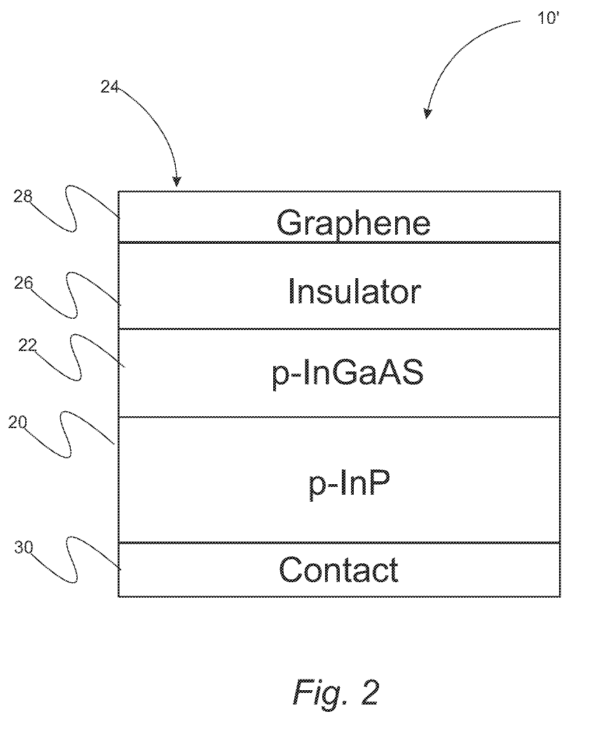

In a variation, HELAC device 10 includes a semiconductor that is sensitive while absorbing photons near 1550 nm is used. This allows well-established high-speed telecom lasers to be utilized. Furthermore, the current density can be increased from about 1 mA/cm² to about 1 A/cm² and experimentally demonstrate that those devices are capable of being modulated at rates 10-250 GHz. FIG. 2 shows a schematic of the III-V structure. Specifically, HELAC device 10′ includes a heavily p-doped indium phosphide (InP) wafer 20. Although not limited by the doping lever in wafer 20, the heavily p-doped indium phosphide wafer has a number density of acceptor atoms from about 1 × 10¹⁶ to about 1 × 10¹⁸ cm⁻³. Although the present variation is not limited by the thickness of the wafer, the typical thickness is about 625 µm ± 25 µm. A lightly doped indium gallium arsenide layer 22 (e.g., In_{0.53}Ga_{0.47}As) is disposed over and optionally contacts heavily p-doped indium phosphide (InP) wafer 20. Although not limited by the doping lever in the indium gallium arsenide layer 22, the lightly doped indium gallium arsenide layer has a number density of acceptor atoms from about 1 × 10¹⁴ to about 0.5 × 10¹⁶ cm⁻³. In a refinement, lightly doped indium gallium arsenide layer 22 has a thickness from about 0.25 to 3 microns. The emitting surface 24 includes insulator layer 26 disposed over and optionally contacts lightly doped indium gallium arsenide layer 22. In a refinement, insulator layer 26 has a thickness from about 5 to 15 nm (e.g., ~10 nm). A monolayer graphene gate 28 is disposed over and optionally contacts insulator layer 26. Advantageously, incident photons generate photoexcited electrons in the InGaAs layer. These photoexcited electrons will be swept to the insulator surface and then tunnel into the graphene, where they will be emitted under the appropriate bias conditions.

Efficient photon to electron conversion in the HELAC devices set forth herein is driven by three processes. First, the absorption of photons will generate electron-hole pairs in the semiconductor, with electrons, swept to the insulator/graphene surface and the holes swept to the p-type contact. The electrons will tunnel across the insulator into the graphene, turning into hot electrons in the graphene. Once in graphene, the hot electrons will either be emitted into the vacuum or thermalize with the other carriers in graphene. The fundamental limits of the time response of these devices can be determined by the transit time of electron-hole pairs generated in the semiconductor and the intrinsic RC constant of the overall structure.

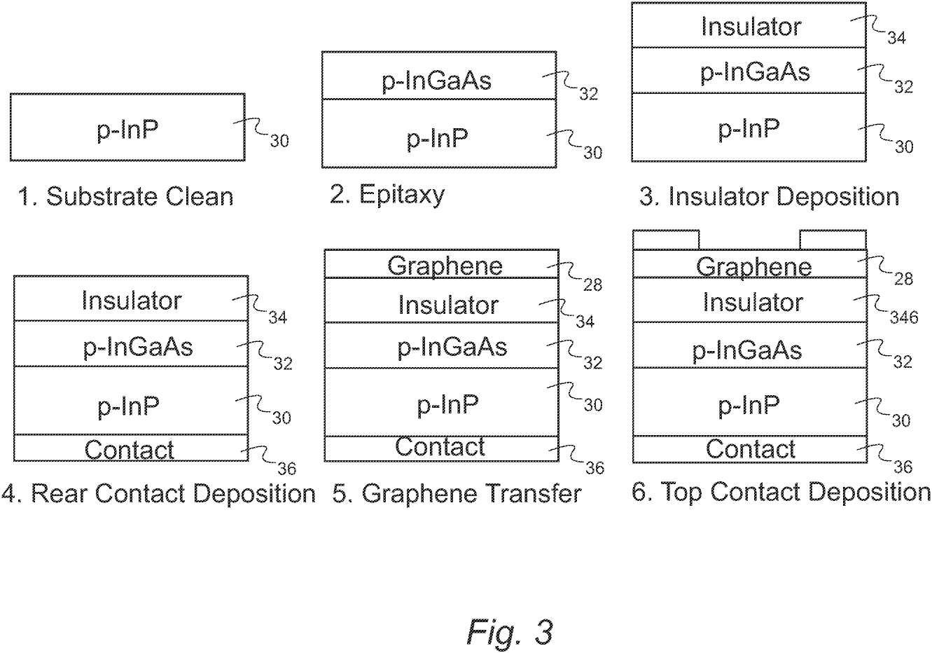

FIG. 3 provides a schematic flowchart illustrating the fabrication flow for the III-V HELACs of FIG. 2. Briefly, starting with substrate wafer 30 (e.g., InP wafer), a clean and epitaxial growth step will be carried out to form semiconductor layer 32. Next, the desired dielectrics for insulator layer 34 is then deposited using a combination of atomic layer deposition (ALD) and plasma-enhanced chemical vapor deposition (PECVD). In a refinement, the dielectrics for the insulating layer can be SiO₂, Si₃N₄, HfO₂, and Al₂O₃. Next, bottom contact 36 is deposited (e.g., sputtering etc.) and then annealed. Graphene layer 38, separately grown, is then be transferred onto the device. Details for preparing graphene layer 38 are provided in Li X, Cai W, An J, Kim S, Nah J, Yang D, Piner R, Velamakanni A, Jung I, Tutuc E, Banerjee SK, Colombo L, Ruoff RS. Large-area synthesis of high-quality and uniform graphene films on copper foils. Science. 2009 Jun 5;324(5932):1312-4. doi: 10.1126/science.1171245. Epub 2009 May 7. PMID: 19423775; the entire disclosure of which is hereby incorporated by reference. The target size of the transferred graphene can be up to 2″ × 2″. Finally, lithography and a mesh top contact 40 will be deposited on the graphene. This grid obscures about 1-3% of the incident photons while minimizing the lateral resistance of the graphene.

In another variation, lattice-matched, lightly doped InGaAs layers of varying thickness are grown on heavily doped p⁺ InP wafers. Advantageously, these layers can be deposited by arsenide and phosphide metal-organic chemical vapor deposition (MOCVD). The InGaAs should have approximately the same lattice constant as the underlying InP wafer. For example, InGaAs with a composition of 53% In and 47% Ga can be grown. Specifically, intrinsic InGaAs can be grown with no intentional doping. Very lightly doped p-type InGaAs with doping concentrations of ~10¹⁵-10¹⁶/cm³ can also be grown. In a refinement, InGaAs layers can be grown with thicknesses of 250 nm - 3 microns, with increments of 250 nm. These epitaxial wafers can serve as the baseline on which HELAC devices are fabricated.

The quality of the grown materials can be evaluated by utilizing X-ray diffraction, which will enable the identification of appropriate lattice matching and will allow the determination of initial quality of the epitaxy. The doping concentration and carrier mobility of these films by growing InGaAs on semi-insulating InP wafers can also be measured with the same conditions and using hall measurements to identify both carrier concentration and mobility. These values will then be utilized in our simulations to accurately simulate our devices.

Additional details are shown in H. U. Chae, R. Ahsan, and R. Kapadia, “Electronically Tunable Negative Electron Affinity Silicon Photoemitters,” 2021 IEEE International Conference on Plasma Science (ICOPS), 2021, pp. 1-1, doi: 10.1109/ICOPS36761.2021.9588524; the entire disclosure of which is hereby incorporated by reference in its entirety.

The following examples illustrate the various embodiments of the present invention. Those skilled in the art will recognize many variations that are within the spirit of the present invention and scope of the claims.

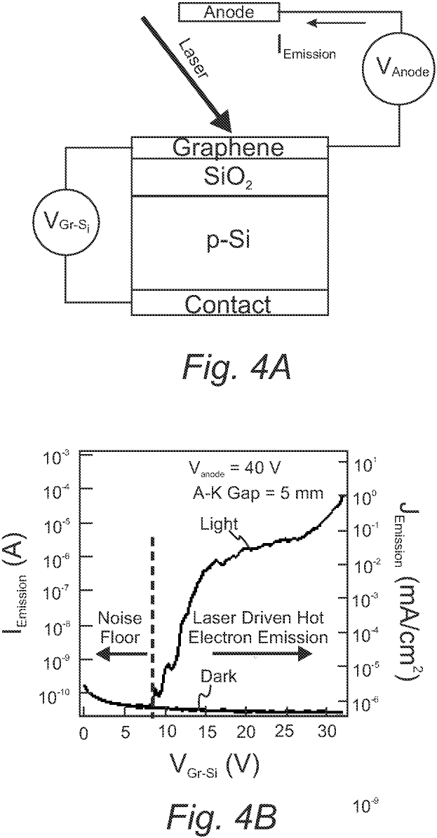

A proof-of-concept HELAC device with a current density of ~1 mA/cm² using a silicon substrate, silicon oxide insulator, and monolayer graphene is demonstrated, as shown in FIG. 4. In this device, a lightly doped p-type silicon wafer (NA=5×10¹⁵ cm⁻³) is used as the substrate, and 10 nm of SiO₂ is deposited on the substrate with plasma-enhanced chemical vapor deposition (PECVD). Then, monolayer graphene is grown on a copper foil and transferred to the substrate. A bias voltage was applied between the graphene and silicon to enable electron photoemission from the silicon.

The electrical characterization circuit for the proof-of-concept HELAC is illustrated in FIG. 4A, with an anode-cathode spacing of 5 mm, an anode bias of 40 V, and a variable graphene-silicon bias. A 45 mW 405 nm laser is used to excite electron-hole pairs in the semiconductor with a spot size of 0.06 cm². FIG. 4B shows the current collected by the anode as the graphene-silicon bias is swept. Critically, the applied field due to the anode is ~8 V/mm, which is orders of magnitude too low to drive field emission from graphene. Thus, when V_{Gr-Si} is low, the measured current is simply the ammeter leakage current. V_{Gr-Si} is the voltade a between the graphene monolayer and the silicon wafer. This is analogous to shining a laser on a silicon substrate-there will be no photoemission. However, once VG_{r-Si} > 8 V, emitted current is observed, despite there being no change in the anode-cathode voltage. This is analogous to shining a laser on a cessiated GaAs surface, resulting in photoemission of carriers. Importantly, the peak current measured for this device is ~70 A, or 1.1 mA/cm2. The incident optical power for this measurement was ~40 mW, leading to an EQE of -0.5%, which is approaching the 1-10% experimentally observed for negative electron affinity photocathodes, despite the lack of any optimization.

Accurate simulation of such a complex process can be carried out by using TCAD Sentaurus to simulate the absorption and transport of carriers inside the semiconductor, and injection into the graphene, and a Graphene Monte-Carlo Boltzmann Transport Solver (gMC-BTE) to calculate the emission of carriers from the graphene into vacuum. The basic framework on which to explore the performance of the HELAC devices and established initial projections has already been constructed.

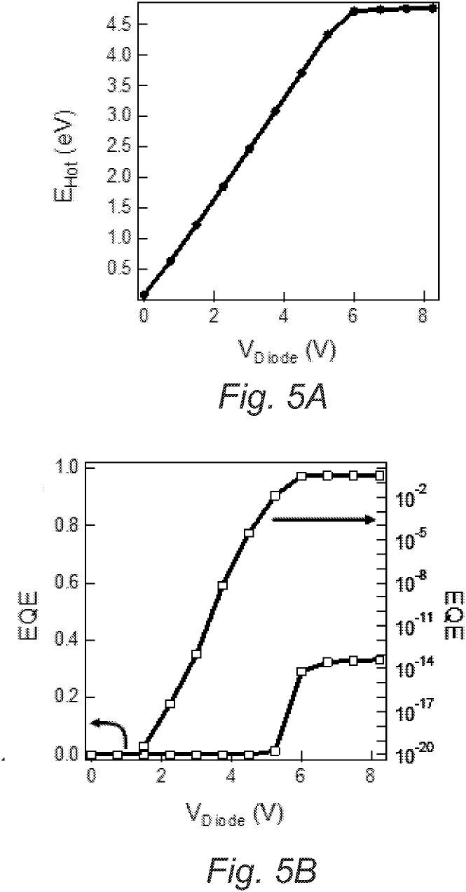

Referring to FIG. 5, the coupled TCAD Sentaurus and the gMC-BTE is used to generate initial performance projections for HELAC III-V devices. FIG. 5A shows the energy above the Dirac point in graphene at which electrons will be injected from the InGaAs. As the Dirac point is 4.5 eV from the vacuum level, photoemission will occur when electrons are injected at energies E_{Hot}>4.5 eV. For this device, the applied diode bias necessary to achieve is observed -5.5 V, which is reasonable and is dramatically lower than the voltage needed for the non-optimized proof-of-concept HELAC. The key factor leading to this drop is the increased tunnel barrier in the optimized HELAC, which enables a greater fraction of the applied bias to be dropped over the tunnel barrier, thus reaching the threshold of photoemission at a significantly lower voltage. FIG. 5B shows the overall simulated external quantum efficiency of this device, which includes losses due to reflection at the surface, recombination losses in the semiconductor, and scattering losses in the graphene. Surprisingly, an EQE of ~30% can be achieved. This high photon-to-electron conversion efficiency leads to the figure of 1.2 A/cm2 emitted current density if excited with a 200 mW laser source with a 0.05 cm2 spot size, which is the currently used spot size.

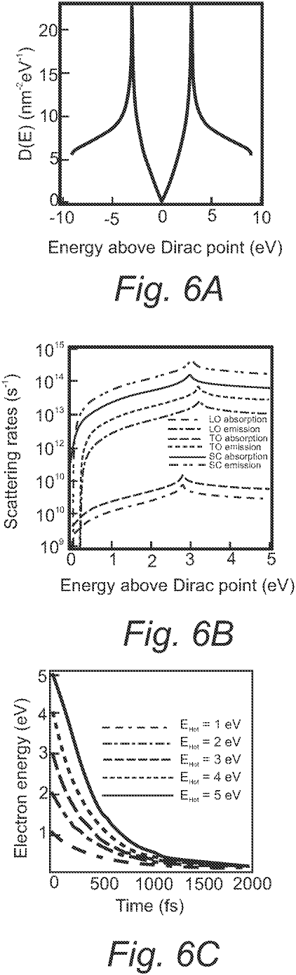

FIG. 6 shows the details of the graphene MCBTE simulator used and the results for hot electron relaxation. Specifically, FIG. 6A shows the density of states in the graphene as a function of energy above and below the Dirac point (which is 4.5 eV below the vacuum level). FIG. 6B shows the scattering rates for longitudinal optical (LO), transverse optical (TO), and super collision (SC) phonon scattering in graphene. These scattering mechanisms, along with electron-electron scattering, is used to predict the hot electron energy loss mechanisms.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A Hot Electron Laser-Assisted Cathode (HELAC) device comprising:
a semiconductor layer that absorbs incident photons;
a graphene monolayer disposed over the semiconductor layer, the graphene monolayer configured as a gate for the HELAC device; and
an insulator layer interposed between the semiconductor layer and graphene monolayer, the insulator layer allowing a voltage drop between the semiconductor layer and graphene, wherein the HELAC device is configured to receive photons on an emitter surface and to emit hot electrons therefrom.

2. The HELAC device of claim 1 in electrical communication with a power supply for positively biasing the graphene monolayer relative to the semiconductor layer.

3. The HELAC device of claim 1, wherein the semiconductor layer is deposited over a wafer substrate.

4. The HELAC device of claim 3, wherein the wafer substrate is a p-doped indium phosphide (InP) wafer.

5. HELAC device of claim 1, wherein the semiconductor layer is an indium gallium arsenide layer.

6. The HELAC device of claim 5, wherein the indium gallium arsenide layer has a thickness from about 0.25 to 3 microns.

7. The HELAC device of claim 1, wherein the insulator layer has a thickness from about 5 to 15 nm.

8. The HELAC device of claim 1, wherein the insulator layer is composed of a dielectric selected from the group consisting of SiO₂, Si₃N₄, HfO₂, and Al₂O₃.

9. The HELAC device of claim 1 wherein the semiconductor layer absorbs photons at or near 1550 nm.

10. The HELAC device of claim 1 wherein current density is from ~1 mA/cm² to 1 A/cm².

11. The HELAC device of claim 1 wherein the HELAC device can be modulated at rates from 10-250 GHz.

12. A method for fabricating a Hot Electron Laser-Assisted Cathode (HELAC) device comprising:
epitaxially depositing a semiconductor layer over a top face of a wafer substrate;
depositing an insulator layer over the semiconductor layer by atomic layer deposition and/or plasma-enhanced chemical vapor deposition;
depositing a bottom contact over a bottom face of the wafer substrate; and
transferring a graphene layer onto the insulator layer.

13. The method of claim 12 further comprising depositing a mesh top contact over the graphene layer.

14. The method of claim 12 wherein the graphene layer is a graphene monolayer.

15. The method of claim 12 wherein the wafer substrate is an InP wafer.

16. The method of claim 12 wherein the insulator layer is composed of a dielectric selected from the group consisting of SiO₂, Si₃N₄, HfO₂, and Al₂O₃.
